(19) United States
(12) Patent Application Publication
(10) Pub. No.: US 2009/0191336 A1
(43) Pub. Date: Jul. 30, 2009

(54) METHOD AND APPARATUS FOR SIMPIFIED STARTUP OF CHEMICAL VAPOR DEPOSITION OF POLYSILICON

(76) Inventors: Mohan Chandra, Merrimack, NH (US); Sankaran Muthukrishnan, Bangalore (IN)

Correspondence Address: Global IP Services, PLLC, 198F, 27th Cross, 3rd Block, Jayanagar, Bangalore, Karnataka, 560011, IN

(21) Appl. No.: 12/022,168

(22) Filed: Jan. 30, 2008

(51) Int. Cl. C23C 16/24

(52) U.S. Cl. 427/248.1; 118/725

(57) ABSTRACT

A simplified startup CVD technique for Siemens type of reactors is disclosed. In one embodiment, a method for production of bulk polysilicon in a CVD reactor assembly includes evacuating stainless steel envelope to have substantially low oxygen content, applying radiant heat (e.g., using a heating element coated with silicon) to the stainless steel enclosure sufficient for raising silicon rods to a firing temperature, flowing process gas (H₂) ladened with a silicon reactant material via a process gas inlet and outlet port, applying sufficient current using low-voltage power supply until the silicon rods reach a deposition temperature of the process gas and upon the silicon reactant material reaching the firing temperature, turning off the radiant heat upon reaching the firing temperature, flowing gaseous byproducts of the CVD process out through the process gas outlet port, and removing as a bulk polysilicon product from the stainless steel enclosure.

### TECHNICAL FIELD OF THE INVENTION

The present invention relates generally to chemical vapor deposition (CVD) reactor, and more particularly relates to method and apparatus for heating silicon rods in the CVD reactor.

### BACKGROUND OF THE INVENTION

One of the widely practiced convention methods of polysilicon production is by depositing polysilicon in a CVD reactor, and is generally referred as Siemens method. In this method, polysilicon is deposited in the CVD reactor on high-purity thin silicon rods called “slim rods”. Because of high purity silicon from which these slim rods are fabricated, the corresponding electrical resistance of the slim rods is extremely high. Thus, it can be extremely difficult to heat the silicon rods using electric current, during the startup phase of the process.

Typically, the silicon rods are brought to a required deposition temperature by direct current passage. They have to be heated beforehand, until the so-called firing temperature is reached at which the ohmic resistance with which they oppose the current flow when a voltage is applied becomes sufficiently low. It is only then that further heating to the deposition temperature takes place by direct current passage. The polyrods produced are an important basic material for the production of high-purity silicon, for example for the production of silicon monocrystals.

In the Siemens method, external heaters are used to raise the temperature of these high purity silicon rods to approximately 400° C. (centigrade) in order to reduce their electrical resistivity. Sometimes external heating is applied in form of halogen heating or plasma discharge heating. However in a typical method, to accelerate the heating process, a very high voltage, in the order of thousands of volts, is applied to the silicon rods to induce resistive heating. Under the high voltage, a small current starts to flow in the silicon rods. This initial flow of current generates heat in the silicon rods, reducing the electrical resistance of the rods and permitting yet higher current flow and generating more heat.

The process of sending low current at high voltage continues until the temperature of the silicon rods reaches about 450° C. At this temperature, the resistance of the high purity silicon rods falls exponentially with temperature. Since the resistivity decreases exponentially with temperature, the current flowing through the silicon rods have to be carefully monitored to prevent burn out. Once the silicon rods start conducting, the high voltage source is switched off and a low voltage source capable of supplying high current is turned on.

In light of the above requirements, the current CVD reactors can require a complex array of subsystems. Two power sources are required; one power supply that can provide very high voltage and low current; and a second power supply that can sustain a very high current at relatively lower voltage. Also needed are the slim rod heaters and their corresponding power supply for preheating the slim rods. Another component is the high voltage switch gear. Moreover, the entire startup process is very cumbersome and time consuming. Since the current drawn by the slim rods at around 450° C. is of a run away nature, the switching of the high voltage to low voltage needs to be done with extreme care and caution.

Another conventional technique uses thin metal rods in place of silicon rods as it is easier to heat metal rods. This is generally known as Rogers-Heinz method. This technique uses tungsten rods as they can be obtained at high purity levels. During the polysilicon deposition, the metal rods become metal-silicides and typically fall off from the polysilicon core when broken. However, each polysilicon, when broken has to be inspected at the core to see if there are any specs of metal. This requires significant grinding, washing and etching at the core before using the polysilicon. Further, this technique is generally not used due to suspicion of a possible contamination and also due to the semiconductor industry requiring higher purity levels.

### SUMMARY OF THE INVENTION

A simplified start up technique for CVD of polysilicon in Siemens method is disclosed. According to an aspect of the subject matter, the CVD includes a base plate including a process gas inlet and outlet port, a cold wall reactor forming a stainless steel envelope attached to the base plate so as to form a closed stainless steel enclosure, a process gas inlet and outlet valve coupled to the process gas inlet and outlet port, one or more power electrodes attached to the base plate, and at least one heating element is disposed substantially in the middle of the one or more silicon rods.

According to another aspect of the subject matter, a method for production of bulk polysilicon in a CVD reactor assembly includes evacuating the stainless steel envelope to have substantially low oxygen content, applying radiant heat (e.g., using at least one heating element coated with silicon) to the stainless steel enclosure, sufficient for raising the one or more silicon rods to a firing temperature (e.g., the firing temperature is in the range of 1000° C. to 1400° C.), and flowing the process gas (e.g., H₂) ladened with a silicon reactant material via the process gas inlet and outlet port. The heating element is made of high purity tungsten, tantalum, molybdenum, high purity graphite, and/or silicon carbide.

The method also includes applying sufficient current using low-voltage power supply until the one or more silicon rods reach a deposition temperature (e.g., approximately 1100° C.) of the process gas and upon the silicon reactant material reaching the firing temperature, turning off the radiant heat upon reaching the firing temperature, flowing gaseous byproducts of the CVD process out through the process gas outlet port, and removing as a bulk polysilicon product from the stainless steel enclosure. In these embodiments, the silicon reactant material is silane, trichlorosilane, dichlorosilane and/or silicon tetrachloride.

### BRIEF DESCRIPTION OF THE DRAWINGS

Example embodiments are illustrated by way of example and not limitation in the figures of the accompanying drawings, in which like references indicate similar elements and in which:

FIG. 1 illustrates a front elevation cut-away view of a CVD reactor, according to an embodiment of the invention.

FIG. 2 is a cross-sectional top view of the CVD reactor assembly shown in FIG. 1, according to an embodiment.

FIG. 3A is a front elevation view of the startup heating element used in the CVD reactor assembly shown in FIGS. 1 and 2, according to an embodiment.

FIG. 3B is a front elevation view of the startup heating element used in the CVD reactor shown in FIGS. 1 and 2, according to another embodiment.

FIG. 4 is a process flow for production of bulk polysilicon by CVD reactor assembly 100, according to one embodiment.

Other features of the present embodiments will be apparent from the accompanying drawings and from the detailed description that follows.

### DETAILED DESCRIPTION OF THE INVENTION

A novel simplified startup CVD technique for Siemens type reactors is disclosed. In the following detailed description of the embodiments of the invention, reference is made to the accompanying drawings that form a part hereof, and in which are shown by way of illustration specific embodiments in which the invention may be practiced. These embodiments are described in sufficient detail to enable those skilled in the art to practice the invention, and it is to be understood that other embodiments may be utilized and that changes may be made without departing from the scope of the present invention. The following detailed description is, therefore, not to be taken in a limiting sense, and the scope of the present invention is defined only by the appended claims.

The terms “silicon rods” and “slim rods” are used interchangeably throughout the document. Also the terms “heater” and “heating element” are used interchangeably throughout the document. Further the terms “CVD reactor” and “CVD reactor assembly” are used interchangeably throughout the document.

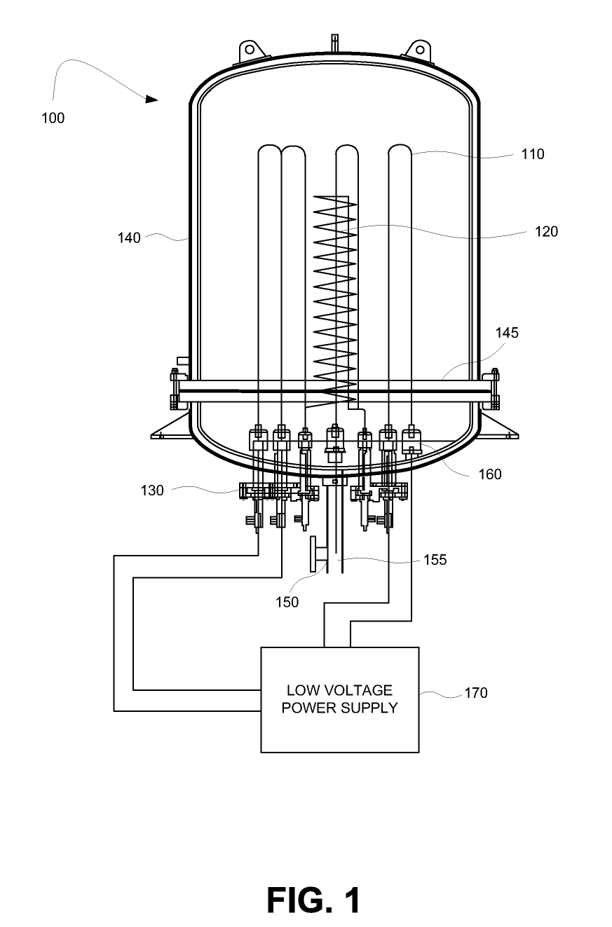

FIG. 1 illustrates a CVD reactor assembly 100, according to an embodiment of the present invention. As shown in FIG. 1, the CVD reactor assembly 100 includes one or more silicon rods 110, a heating element 120, one or more power electrodes 130 associated with the one or more silicon rods 110, a cold wall reactor 140, a base plate 145, a process gas inlet/outlet port 150, a process gas inlet and outlet valve 155, one or more graphite support assemblies 160, and a low-voltage power supply 170.

Further as shown in FIG. 1, the CVD reactor assembly 100 includes the base plate 145 including the process gas inlet and outlet port 150, and the cold wall reactor 140 attached to the base plate 145. In some embodiments, the cold wall reactor 140 forming a stainless steel envelope attached to the base plate 145 so as to form a closed stainless steel enclosure. The CVD reactor assembly 100 also includes the process gas inlet and outlet valve 155 coupled to the process gas inlet and outlet port 150 such that the process gas inlet and outlet valve 155 is communicatively coupled with the interior of the stainless steel envelope.

As shown in FIG. 1, the CVD reactor assembly 100 also includes the one or more power electrodes 130 attached to the base plate 145. The CVD reactor assembly 100 further includes the one or more silicon rods 110 disposed substantially in the stainless steel envelope. In some embodiments, the silicon rods 110 are disposed substantially vertically in the stainless steel envelope. Further, the silicon rods 110 are electrically coupled to the one or more power electrodes 130.

Also, the CVD reactor assembly 100 includes the heating element 120 disposed substantially in the middle of the one or more silicon rods 110. As shown in FIG. 1, the heating element 120 is disposed substantially vertically in the middle of the one or more silicon rods 110. In some embodiments, the heating element 120 is coupled to the base plate 145. In these embodiments, the heating element 120 emits radiant heat.

Further, the heating element 120 is a thin filament made from high purity tungsten, molybdenum, high purity graphite, or silicon carbide. The high purity tungsten may contain a metal composition of 99.95% or more and the high purity graphite is of a semiconductor grade. In one example embodiment, the high purity tungsten heating element 120 emits radiant heat having a color temperature of about 1300° C. In another example embodiment, the high purity graphite heating element emits radiant heat having a color temperature of approximately 2000° C.

In some embodiments, the thin filament is coated with a substantially thin layer of silicon to prevent any exposure of metal to process gases. In these embodiments, the process gas is hydrogen (H₂). Further, the thin filament is coupled to the filament power electrodes that supply power. For example, the thin filament is disposed in spiral, elliptical, rectangular, square shapes and the like.

Further as shown in FIG. 1, the CVD reactor assembly 100 includes one or more graphite support assemblies 160 substantially disposed onto the one or more power electrodes 130 to support the one or more silicon rods 110 and the heating element 120. As illustrated in FIG. 1, the CVD reactor assembly 100 also includes the low-voltage power supply 170 coupled to the heating element 120.

In operation, the heating element 120 is used for heating the silicon rods 110 during startup, in the CVD reactor 100. In these embodiments, the heating element 120 is configured to be disposed substantially in the middle of the silicon rods. For example, the heating element 120 emits radiant heat having a color temperature of approximately 2500° C. The radiant heat sufficient for raising the silicon rods 110 to a firing temperature is applied to the stainless steel enclosure using the heating element 120.

The process gas (i.e., H₂) ladened with a silicon reactant material is flown through the process gas inlet and outlet port 150 coupled to the process gas inlet and outlet valve 155. Further, the low-voltage power supply 170 applies sufficient current to the silicon rods 110 until the silicon rods 110 reach the decomposition temperature of the process gas and upon the silicon reactant material reaching the firing temperature. Further, when the temperature of the silicon rods 110 reaches the firing temperature, the radiant heat is turned off by shutting off the power to the heating element 120. In these embodiments, the gaseous byproducts obtained during the CVD process are flown out through the process gas outlet port 150. Finally, the bulk polysilicon product obtained during the CVD process in the CVD reactor 100 is removed from the stainless steel enclosure.

In accordance with the above mentioned embodiments, the radiant heat from the tungsten rods (i.e., the heating element 120) reaches the silicon rods 110 in an atmosphere of hydrogen (H₂). The tungsten heaters can be quickly taken to elevated temperatures, thus allowing the radiation heat and convention heat to heat the silicon rods 110 efficiently to the firing temperature. Once the silicon rods 110 reach the firing temperature, i.e., once the silicon rods 110 are hot enough for conduction by absorption of the radiant heat, the CVD process can be started using low-voltage power supplies such as the low-voltage power supply 170. Then the heaters 120 (e.g., the tungsten rods) remain in the switched off condition in the CVD reactor 100 during the CVD process which results in minimal silicon deposition on the heaters 120. Therefore, the tungsten rods can be reused until they break. Further, it can be seen that the use of tungsten rods in the CVD process is a simple and inexpensive replacement.

As illustrated above, the heaters 120 are positioned substantially in the middle of the slim-rod assembly 110 as shown in FIG. 1 and initially the heat radiates out though the slim-rod assembly 110 to the cold walls and in the process, the silicon rods 110 pick-up the heat via radiation. As the H₂ enters the cold wall reactor 140 from the center through the process gas inlet and outlet port 150, the heat from the heater 120 also reaches the silicon rods via convection as well. In one embodiment, the silicon rods 110 are heated efficiently to the firing temperature through the radiation heat and the convention heat.

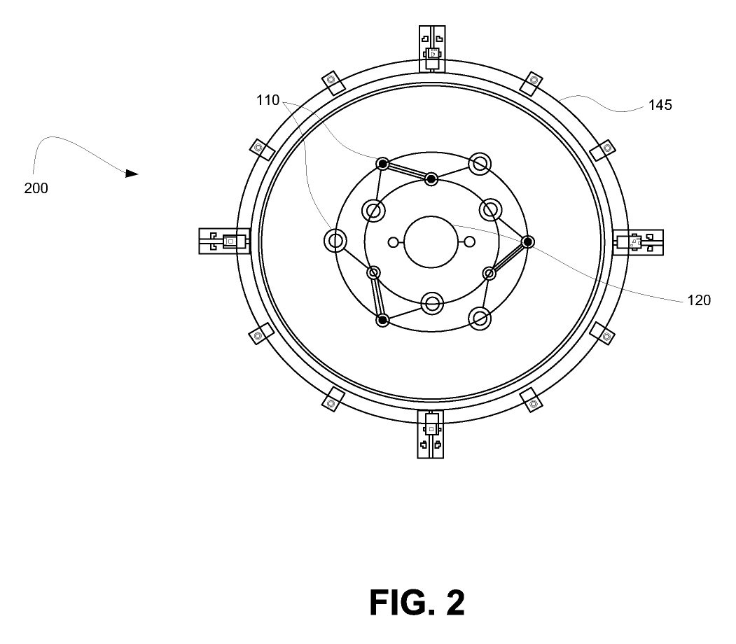

FIG. 2 is a cross-sectional top-view 200 of the CVD reactor assembly 100 shown in FIG. 1, according to an embodiment. Particularly, FIG. 2 depicts the silicon rods 110, the heating element 120 and the base plate 145. As shown in FIG. 2, the heating element 120 is disposed substantially vertically in the middle of the silicon rods 110 and also located at the center of the base plate 145. As shown in FIG. 2, the silicon rods 110 are arranged around the heating element 120 such that the heating element 120 is disposed substantially vertically in the middle of the silicon rods 110. Further, the cold wall reactor 140 forming the stainless steel envelope attached to the base plate 145 so as to form the closed stainless steel enclosure.

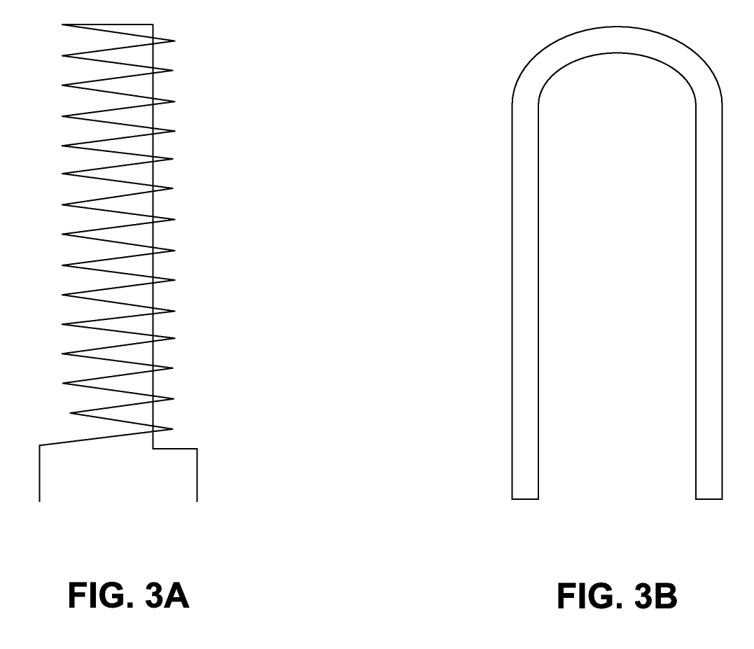

FIGS. 3A and 3B illustrate two different embodiments of the heating elements 120 that can be used in the CVD reactor assembly 100, such as the CVD reactor assembly 100 shown in FIGS. 1 and 2. In one example embodiment, FIG. 3A illustrates the heating element 120 of spiral shape. In another example embodiment, FIG. 3B illustrates the heating element 120 of elliptical shape. Although the two different embodiments illustrated in FIGS. 3A and 3B represent the spiral and elliptical shaped heating elements respectively, heating elements of other shape such as rectangular, square, octagonal, circular, etc., is with in the scope of the invention.

Further, the heating element 120 is a thin filament made of high purity tungsten, molybdenum, high purity graphite or silicon graphite. In one embodiment, the tungsten heating element emits radiant heat having a color temperature of about 1300° C. whereas, the graphite heating element emits radiant heat having a color temperature of at least 2000° C.

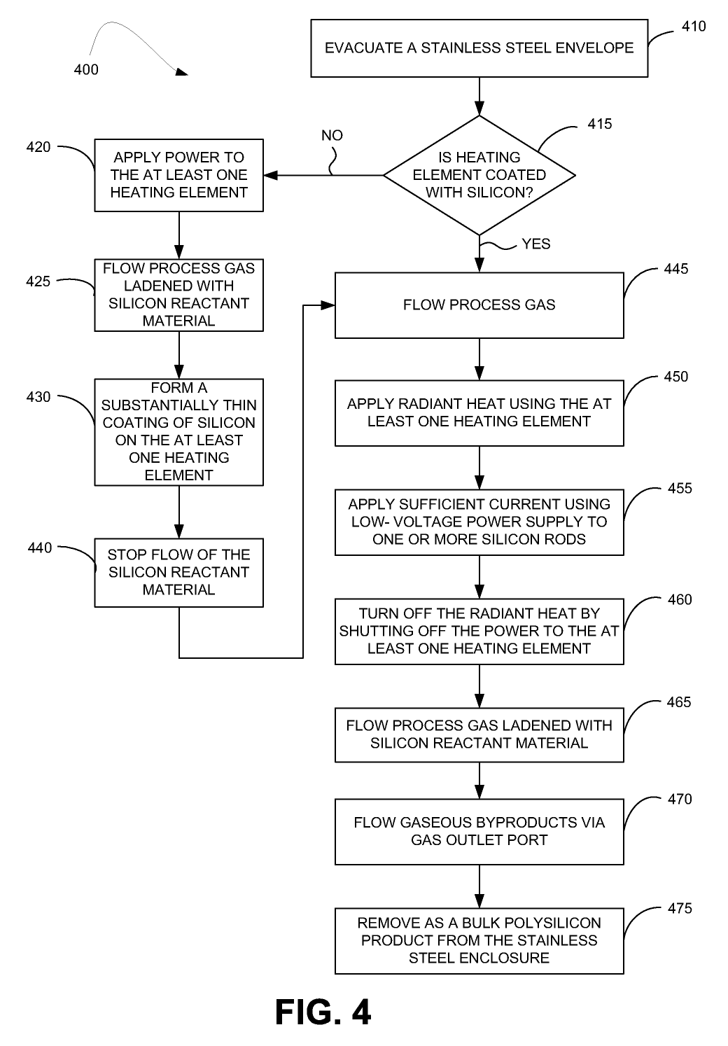

FIG. 4 is a process flow 400 for production of bulk polysilicon by CVD reactor assembly 100, according to one embodiment. In operation 410, a stainless steel envelope is evacuated to have substantially low oxygen contact. In operation 415, the process 400 determines whether a heating element 120 is coated with silicon. If the heating element 120 is not coated with silicon, then the operations 420 to 440 are performed for coating the heating element 120 with silicon.

In operation 420, sufficient current is applied (e.g., using a power supply) to the heating element 120 of the stainless steel enclosure, sufficient for raising the heating element 120 to the deposition temperature. In operation 425, process gas ladened with a silicon reactant material is flown via the process gas inlet and outlet port 150. In some embodiments, the process gas is H₂ and the silicon reactant material is silane, trichlorosilane, dichlorosilane, silicon tetrachloride, etc.

In operation 430, a substantially thin coating of silicon, sufficient to prevent metal exposure on the heating element 120 is formed. In operation 440, flow of the silicon reactant material is stopped upon forming the substantially thin coating of silicon, sufficient to prevent the metal exposure on the heating element 120.

In operation 415, if the heating element 120 is coated with silicon, then operation 445 is performed directly without performing the operations 420 to 440. The process 400 goes to the operation 445 either from operation 415 or from operation 440, based on the determination made in operation 415.

In operation 445, process gas (H₂) is flown via the process gas inlet and outlet port 150. In operation 450, radiant heat, sufficient for raising the silicon rods 110 to a firing temperature is applied to the stainless steel enclosure using the heating element 120. In some embodiments, in applying radiant heat (e.g., using the heating element 120) to the stainless steel enclosure, sufficient for raising the heating element 120 to the deposition temperature, the deposition temperature is about 1100° C.

In operation 455, sufficient current is applied (e.g., using the low-voltage power supply 170) to the silicon rods 110 until the silicon rods 110 reach the deposition temperature of the process gas (H₂) and upon the silicon reactant material, reaching the firing temperature. In some embodiments, in applying sufficient current using low-voltage power supply 170 until the silicon rods 110 reach the deposition temperature of the process gas (H₂) and upon the silicon reactant material reaching the firing temperature, the firing temperature is in the range of 1000° C. to 1400° C.

In operation 460, the radiant heat is turned off by shutting off the power to the heating element 120 upon reaching the firing temperature. In operation 465, the process gas (H₂) ladened with a silicon reactant material is flown via the process gas inlet and outlet port 150. In operation 470, gaseous byproducts of the CVD process are flown out through the process gas outlet port 150. In operation 475, polysilicon product is removed as a bulk from the stainless steel enclosure.

It can be seen that the above-described technique does not require high voltages for the startup of the CVD of polysilicon in Siemens type of reactors. For example, the above technique uses high purity tungsten rods as heaters which otherwise could have been used as deposition media. As illustrated above, the tungsten rods remain in the switched off condition in the CVD reactor 100 during the CVD process (i.e., once the CVD process starts) which results in minimal silicon deposition on the heaters 120. Therefore, the tungsten rods can be reused until they break. It can be seen that it is a simple and inexpensive replacement.

Further, the tungsten heaters do not get hot enough for any silicon deposition as most of the generated heat is radiated out to the cold walls and the tungsten heaters have a significantly low thermal mass. As it can be seen, there can be only a small amount of silicon deposition on the tungsten heaters which may be of no significant consequence to the CVD process. Further, any silicon deposition on the tungsten heaters will only assist in not exposing the tungsten during the CVD process, thus prohibiting any impurity transport from the tungsten to the silicon rods 110. Also, it can be seen that the above technique does not require any opening of the CVD reactors and inserting the heaters during the CVD process. Also, the above technique provides all the needed power to the heaters via the water cooled electrodes from the base plate 145.

Also, it can be seen that the CVD reactor 100 can be turned on again quickly when there is a power interruption or shut-down. If required, the tungsten heater temperature can be raised quickly to temperatures as high as 2000° C. using very little power as low wattages are required to heat the tungsten heaters. It can also be envisioned that various designs of tungsten heaters can be designed and two such embodiments are shown in FIGS. 3A and 3B. It can be noted that other materials such as molybdenum, high purity graphite, silicon carbide, etc can also be used as heating element 120 in the context of the invention.

Although the present embodiments have been described with reference to specific example embodiments, it will be evident that various modifications and changes may be made to these embodiments without departing from the broader spirit and scope of the various embodiments.

In addition, it will be appreciated that the various operations, processes, and methods disclosed herein may be embodied in a machine-readable medium and/or a machine accessible medium compatible with a data processing system (e.g., a computer system), and may be performed in any order. Accordingly, the specification and drawings are to be regarded in an illustrative rather than a restrictive sense.

1. A device for heating silicon rods during startup in a chemical vapor deposition (CVD) reactor, comprising:
at least one heating element configured to be disposed substantially in the middle of the silicon rods and wherein the at least one heating element emits radiant heat having a color temperature of at least 2500° C.

2. The device of claim 1, wherein the at least one heating element is a thin filament made from materials selected from the group consisting of high purity tungsten, tantalum, molybdenum, high purity graphite, and silicon carbide.

3. The device of claim 2, wherein the thin filament is coupled to filament power electrodes that supply power.

4. The device of claim 2, wherein the thin filament is disposed in shapes selected from the group consisting of spiral, elliptical, rectangular, and square.

5. The device of claim 2, wherein the thin filament is coated with a substantially thin layer of silicon to prevent any exposure of metal to process gasses.

6. An enclosed cold wall CVD reactor assembly, comprising:
a base plate including a process gas inlet and outlet port;
a cold wall reactor forming a stainless steel envelope attached to the base plate;
a process gas inlet and outlet valve coupled to the process gas inlet and outlet port such that the process gas inlet and outlet valve is communicatively coupled with the interior of the stainless steel envelope;
one or more power electrodes attached to the base plate;
one or more silicon rods disposed substantially in the stainless steel envelope and electrically coupled to the one or more power electrodes; and
at least one heating element is disposed substantially in the middle of the one or more silicon rods and coupled to the base plate and wherein the at least one heating element emits radiant heat.

7. The CVD reactor assembly of claim 6, wherein the one or more silicon rods are disposed substantially vertically in the stainless steel envelope.

8. The CVD reactor assembly of claim 6, wherein the at least one heating element is disposed substantially vertically in the middle of the one or more silicon rods.

9. The CVD reactor assembly of claim 6, further comprising:
a low-voltage power supply coupled to the at least one heating element.

10. The CVD reactor assembly of 6, further comprising:
one or more graphite support assemblies substantially disposed onto the one or more power electrodes to support the one or more silicon rods and the at least one heating element

11. The CVD reactor assembly of claim 9, wherein the at least one heating element is a thin filament made from materials selected from the group consisting of tungsten, tantalum, molybdenum, graphite, and silicon carbide.

12. The CVD reactor assembly of claim 11, wherein the thin filament is coated with a substantially thin layer of silicon to prevent any exposure of metal to process gasses.

13. The CVD reactor assembly of claim 6, wherein the process gas comprises hydrogen (H₂).

14. The CVD reactor assembly of claim 6, wherein the at least one heating element is a tungsten heating element that emits radiant heat having a color temperature of about 1300° C.

15. The CVD reactor assembly of claim 6, wherein the at least one heating element is made of a graphite that emits radiant heat having a color temperature of at least 2000° C.

16. A method for production of bulk polysilicon in a CVD reactor assembly, wherein the CVD reactor assembly comprising a base plate including a process gas inlet and outlet port, a cold wall reactor forming a stainless steel envelope attached to the base plate so as to form a closed stainless steel enclosure, a process gas inlet and outlet valve coupled to the process gas inlet and outlet port, one or more power electrodes attached to the base plate, and at least one heating element is disposed substantially in the middle of the one or more silicon rods, comprising
evacuating the stainless steel envelope to have substantially low oxygen content;
determining whether the at least one heating element is coated with silicon;
if so, applying radiant heat using the at least one heating element to the stainless steel enclosure sufficient for raising the one or more silicon rods to a firing temperature;
flowing the process gas ladened with a silicon reactant material via the process gas inlet and outlet port;
applying sufficient current using low-voltage power supply until the one or more silicon rods reach a deposition temperature of the process gas and upon the silicon reactant material reaching the firing temperature;
turning off the radiant heat upon reaching the firing temperature;
flowing gaseous byproducts of the CVD process out through the process gas outlet port; and
removing as a bulk polysilicon product from the stainless steel enclosure.

17. The method of claim 16, further comprising:
if not, applying sufficient current using a power supply to the at least one heating element to the stainless steel enclosure sufficient for raising the at least one heating element to the deposition temperature;
flowing the process gas ladened with a silicon reactant material via the process gas inlet and outlet port;
forming a substantially thin coating of silicon sufficient to prevent metal exposure on the at least one heating element; and
stop flowing of the silicon reactant material.

18. The method of claim 17, wherein, in applying radiant heat using the at least one heating element to the stainless steel enclosure sufficient for raising the at least one heating element to the deposition temperature, the deposition temperature is about 1100° C.

19. The method of claim 16, wherein, in applying sufficient current using low-voltage power supply until the one or more silicon rods reach the deposition temperature of the process gas and upon the silicon reactant material reaching the firing temperature, the firing temperature is in the range of 1000° C. to 1400° C.

20. The method of claim 16, wherein the process gas is H₂

21. The method of claim 16, wherein the silicon reactant material is selected from the group consisting of silane, trichlorosilane, dichlorosilane and silicon tetrachloride.
